(19) United States
(12) Patent Application Publication
(10) Pub. No.: US 2013/0258750 A1
(43) Pub. Date: Oct. 3, 2013

(54) DUAL-CELL MTJ STRUCTURE WITH INDIVIDUAL ACCESS AND LOGICAL COMBINATION ABILITY

(71) Applicants: JAE-JOON KIM, Yorktown Heights, NY (US); RAHUL M. RAO, Austin, TX (US)

(72) Inventors: JAE-JOON KIM, Yorktown Heights, NY (US); RAHUL M. RAO, Austin, TX (US)

(73) Assignee: INTERNATIONAL BUSINESS MACHINES CORPORATION, ARMONK, NY (US)

(21) Appl. No.: 13/435,000

(22) Filed: Mar. 30, 2012

(51) Int. Cl. G11C 11/22; G11C 11/16

(52) U.S. Cl. 365/145; 365/158

(57) ABSTRACT

A dual-cell spin-transfer torque random-access memory including a first magnetic tunneling junction and a second magnetic tunneling junction. An access circuit is coupled to the first and second magnetic tunneling junctions such that independent read and write access is provided to bits stored in the first and second magnetic tunneling junctions.

### BACKGROUND

1. Technical Field

The present invention relates to memory technology, and more particularly to a dual-cell spin-transfer torque random-access memory (STTRAM) that provides independent read and write access to each cell and a logical combination of both cells implemented as a single read operation.

2. Description of the Related Art

Conventional electric charge based memory technologies such as static random-access memory (SRAM) and dynamic random-access memory (DRAM) face significant challenges meeting the ever increasing demands of mobile and datacenter applications. The current state-of-the-art complimentary metal-oxide-semiconductor (CMOS) technology on which SRAM and DRAM cells are based faces inherent limitations in achieving increased scalability, lower power dissipation and improved manufacturing consistency.

Magnetic field based memories such as Magnetoresistive random-access memory (MRAM) face similar challenges in meeting the needs of mobile and datacenter applications. Specifically, a high current is required to induce the magnetic field needed to perform a write operation to a MRAM, this translating into higher power requirements. Moreover, scalability of MRAM is limited due to magnetic interference among neighboring cells within the MRAM resulting in increased write errors.

Furthermore, a read operation in most conventional memory technologies generally accesses a single stored bit. If a logical combination is to be performed on two stored bits, each stored bit must be individually read out and provided to circuitry external to the memory that implements the logical combination. As such, two read operations and additional external circuitry are each required. Moreover, those conventional memory structures that do provide an internal logical combination do not implement the logical operation as a single read operation. Rather, they require multiple read operations and do not provide individual read and write access directly to the cells involved in the logical combination.

### SUMMARY

In accordance with the present principles, a dual-cell spin-transfer torque random-access memory includes a first magnetic tunneling junction and a second magnetic tunneling junction. An access circuit coupled to the first and second magnetic tunneling junctions provides independent read and write access to bits stored in the first and second magnetic tunneling junctions.

In accordance with the present principles a dual-cell spin-transfer torque random-access memory includes a first magnetic tunneling junction and a second magnetic tunneling junction. A first transistor and a second transistor provide independent read and write access to bits stored in the first and second magnetic tunneling junctions and also provide a logical combination of bits stored in the first and second magnetic tunneling junctions.

In accordance with the present principles, a method of accessing a dual-cell spin-transfer torque random-access memory includes the steps of generating a current flow through a first magnetic tunneling junction to access a first cell. Generating a current flow through a second magnetic tunneling junction to access a second cell. Generating a current flow through both the first and the second magnetic tunneling junctions in series to access a logical combination of the first and second cells.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a schematic view of an embodiment of a dual-cell spin-transfer torque random-access memory (STTRAM) according to the present principles;

FIG. 2 is a schematic view of a write operation of a first single-bit for one illustrative embodiment of the dual-cell STTRAM according to the present principles;

FIG. 3 is a schematic view of a write operation of a second single-bit for one illustrative embodiment of the dual-cell STTRAM according to the present principles;

FIG. 4 is a schematic view of a read operation of a first single-bit for one illustrative embodiment of the dual-cell STTRAM according to the present principles;

FIG. 5 is a schematic view of a read operation of a second single-bit for one illustrative embodiment of the dual-cell STTRAM according to the present principles;

FIG. 6 is a block/flow diagram of a method for independently accessing first and second cells within an illustrative embodiment of the dual-cell STTRAM according to the present principles;

FIG. 7 is a schematic view of a read operation of a logical combination of the first and second cells for one illustrative embodiment of dual-cell STTRAM according to the present principles;

FIG. 8 is a block/flow diagram of a method for read operation of a logical combination of the first and second cells within an illustrative embodiment of the dual-cell STTRAM according to the present principles; and

FIG. 9 is a schematic view of another illustrative embodiment of a dual-cell STTRAM according to the present principles.

### DETAILED DESCRIPTION OF PREFERRED EMBODIMENTS

According to the embodiments of the present principles, a dual-cell spin-transfer torque random memory configuration is provided with an access circuit that provides individual access to each of two cells as well as access to a logical combination of the two cells implemented. The components of the access circuit in an illustrative embodiment may include two magnetic tunneling junctions and two transistors. Furthermore, the access circuit in an illustrative embodiment may provide input and output lines including a read line, a write line and three bit lines.

It will be understood that when an element such as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A design for an integrated circuit chip may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used in the fabrication of integrated circuit chips. The chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

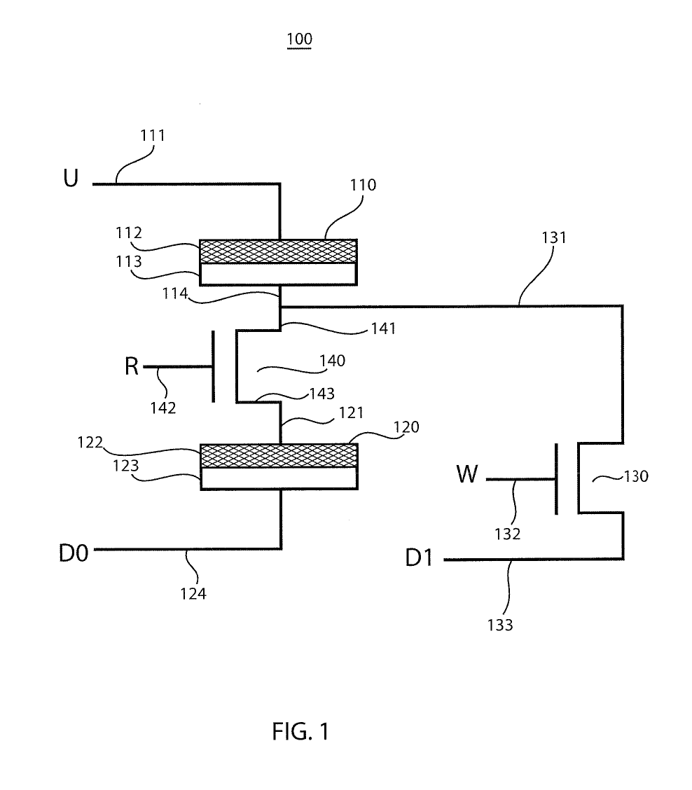

Referring now to the drawings in which like numerals represent the same or similar elements and initially to FIG. 1, a schematic view of an embodiment of a dual-cell spin-transfer torque random-access memory (STTRAM) according to the present principles is illustrated. As shown in FIG. 1, dual-cell STTRAM 100 includes a first magnetic tunneling junction (MTJ) 110, a second MTJ 120, a first transistor 130 and a second transistor 140. First MTJ 110 includes a ferromagnetic pinned layer 113, a ferromagnetic free layer 112, and a non-magnetic tunnel barrier layer (Not Shown) between pinned layer 113 and free layer 112. Similarly, second MTJ 120 includes a ferromagnetic pinned layer 123, a ferromagnetic free layer 122, and a non-magnetic tunnel barrier layer (Not Shown) between pinned layer 123 and free layer 122.

Pinned layers 113 and 123 each have a magnetic orientation that is fixed whereas free layers 112 and 122 each have a magnetic orientation that is changeable. The magnetic orientation of pinned layers 113 and 123 may be pinned using an antiferromagnetic layer or any other method known to one of ordinary skill in the art. The tunnel barrier layers (not shown) may be composed of any non-magnetic metallic material or any non-magnetic metal oxide material known to one of ordinary skill in the art.

First MTJ 110 stores a first single-bit and second MTJ 120 stores a second single-bit. The logic value of a single-bit written to an MTJ is defined by the magnetic orientation of the free layer relative to the pinned layer. If the magnetic orientation of the free layer is parallel relative to the orientation of the pinned layer, the resistance of the MTJ is low which corresponds to 0 logic value. Alternatively, if the magnetic orientation of the free layer is anti-parallel relative to the magnetic orientation of the pinned layer, the resistance of the MTJ is high which corresponds to 1 logic value.

First transistor 130 includes a gate 132, a drain 131 and a source 133. Similarly, second transistor 140 includes a gate 142, a drain 141 and a source 121. These transistors are described in this embodiment of the present principles as negative field effect transistors. However, one of ordinary skill in the art will note that other transistor types may be used to provide similar functionality.

Second transistor 140 is positioned between first MTJ 110 and second MTJ 120 with drain 141 electrically coupled to pinned layer 113 of first MTJ 110 and source 143 electrically coupled to free layer 122 of second MTJ 120. First MTJ 130 is positioned with drain 131 electrically coupled to pinned layer 113 of first MTJ 110.

Dual-cell STTRAM 100 also includes three bit lines. A first bit line (D1) is electrically coupled to source 133 of first transistor 130. A second bit line (D0) is electrically couples to pinned layer 123 of second MTJ 120. A third bit line (U) is electrically coupled to free layer 112 of first MTJ 110. Furthermore, dual-cell STTRAM 100 includes a read line (R) electrically coupled to gate 142 of second transistor 140 and a write line (W) electrically coupled to gate 132 of first transistor 130.

Accordingly, an illustrative embodiment of a dual-cell STTRAM 100 according to the present principles includes an access circuit that may include two MTJs, two transistors, three bit lines, a read line and a write line. This access circuit within a single STTRAM provides for independent access to each of two single-bits stored within the dual-cell STTRAM. As will be noted by one of ordinary skill in the art, the access circuit described in the illustrative embodiment may be designed using other devices and configurations capable of providing the same described access to each of two single-bits stored within a dual-cell STTRAM.

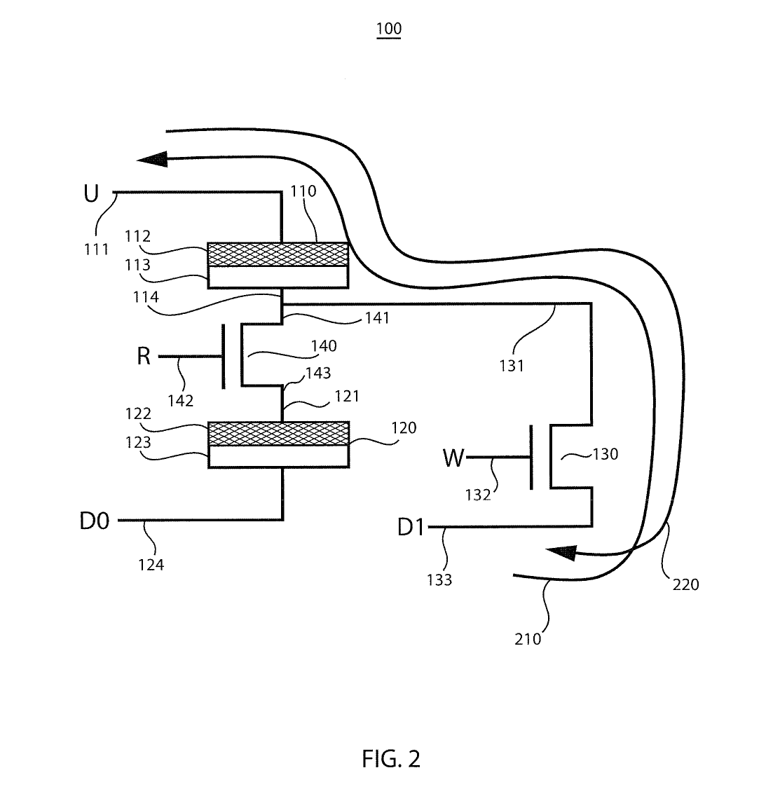

Referring to FIG. 2, a schematic view of a write operation of a first single-bit for one illustrative embodiment of the dual-cell STTRAM according to the present principles is illustrated. As shown in FIG. 2, the first single-bit is written to first MTJ 110 by a current flowing through first MTJ 110 via first transistor 130. Specifically, gate 132 (W) is set high to turn on first transistor 130 and gate 142 (R) is set low to turn off second transistor 140. A voltage sufficient to create a current flow whose magnitude can affect the magnetic orientations of free layer 112 is applied across first bit line 133 (D1) and third bit line 111 (U).

The value of the first single-bit written to MTJ 110 depends on the direction of the current generated between first bit line 133 (D1) and third bit line (U). If a current flow 220 from third bit line 111 (U) to first bit line 133 (D1) is generated, the magnetic orientation of free layer 112 is aligned parallel relative to that of pinned layer 113.

Specifically, downward current flow 220 creates an upward flow of electrons passing first through pinned layer 133 and then through free layer 112. As the flow of electrons pass through pinned layer 113, their spin is aligned with the magnetic orientation of pinned layer 113 thereby creating a spin-polarized current. When this spin-polarized current then flows through free layer 112, the angular momentum of the polarized electrons is transferred to free layer 112 thereby aligning the magnetic orientation of free layer 112 parallel relative to the magnetic orientation of pinned layer 113. This parallel orientation of the magnetic fields results in first MTJ 110 having a low resistance which corresponds to a 0 logic value.

Alternatively, an upward current 210 creates a downward flow of electrons passing first through free layer 112 and then though pinned layer 113. As electrons pass though free layer 112 and reach pinned layer 113, a minority of electrons whose spin is not aligned with the magnetic orientation of pinned layer 113 are reflected back into free layer 112. These minority spin-oriented electrons have sufficient angular momentum to align the magnetic orientation of free layer 112 anti-parallel relative to the magnetic orientation of pinned layer 113. This anti-parallel orientation of the magnetic fields results in first MTJ 110 having a high resistance corresponding to a 1 logic value.

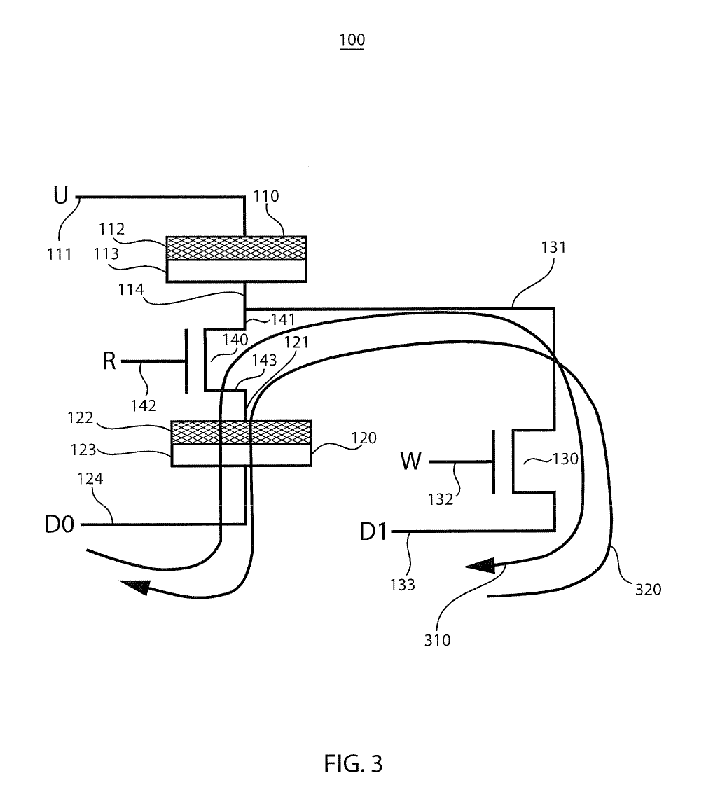

Referring to FIG. 3, a schematic view of a write operation of a second single-bit for one illustrative embodiment of the dual-cell STTRAM according to the present principles is illustrated. As shown in FIG. 3, a second single-bit is written to second MTJ 120 by a current flowing through second MTJ 120 via first transistor 130 and second transistor 140 in series. Specifically, gate 132 (W) and gate 142 (R) are each set high to turn on both first transistor 130 and second transistor 140. Third bit line 111 (U) and first bit line 133 (D1) are set to the same voltage. A voltage sufficient to create a current flow whose magnitude can affect the magnetic orientation of free layer 122 is then applied across second bit line 124 (D0) and first bit line 133 (D1).

As discussed above, the value of the second single-bit written to MTJ 120 depends on the direction of the current generated between second bit line 124 (D0) and first bit line 133 (D1). If a current flow 310 from second bit line 124 (D0) to first bit line 133 (D1) is generated, the magnetic orientation of free layer 122 is aligned anti-parallel relative to that of pinned layer 123. This anti-parallel orientation of the magnetic fields results in second MTJ 120 having a high resistance corresponding to a 1 logic value.

Alternatively, if a current flow 320 from first bit line 133 (D1) to second bit line 124 (D0) is generated, the magnetic orientation of free layer 122 is aligned parallel relative to that of pinned layer 123. This parallel orientation of the magnetic fields results in second MTJ 120 having a low resistance corresponding to a 0 logic value.

Accordingly, an illustrative embodiment of a dual-cell STTRAM embodiment of the present principles includes an access circuit capable of storing two single-bits of data and capable of providing independent write operations to each of the cells with a dual-cell STTRAM. As will be noted by one of ordinary skill in the art, the access circuit described in the illustrative embodiment may be designed using other devices and configurations capable of storing two single-bits of data and capable of providing independent write operations to each of the cells in a dual-cell STTRAM.

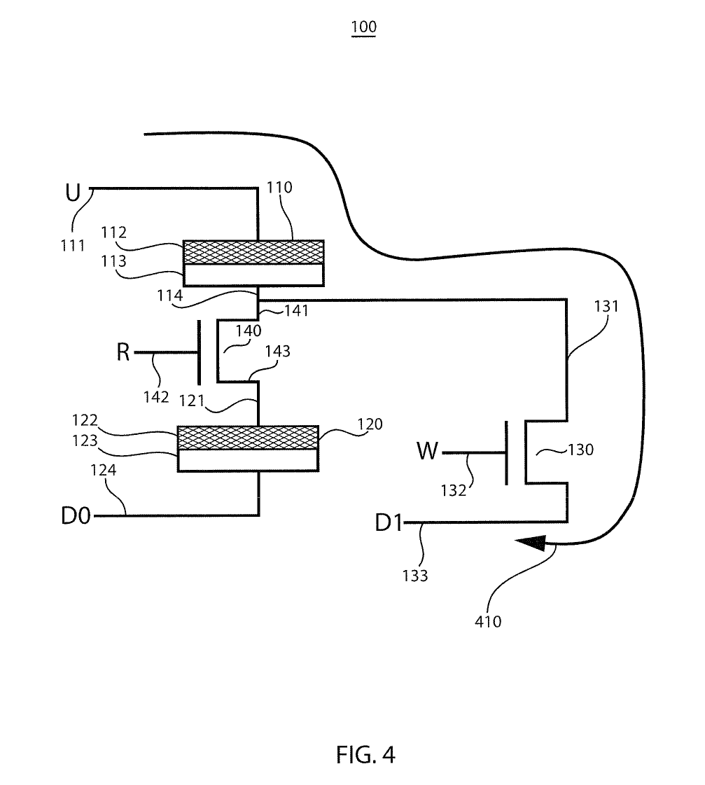

Referring to FIG. 4, a schematic view of a read operation of a first single-bit for one illustrative embodiment of the dual-cell STTRAM according to the present principles is illustrated. As shown in FIG. 4, the first single-bit stored in MTJ 110 is read by passing a sense current 410 through first MTJ 110 via first transistor 130. Specifically, gate 132 (W) is set high to turn on first transistor 130 and gate 142 (R) is set low to turn off second transistor 140. A voltage sufficient to generate sense current 410 through first MTJ 110 is applied across third bit line 111 (U) and first bit line 133 (D1). The magnitude of sense current 410 is not sufficient to affect the magnetic orientation of free layer 112 of first MTJ 110. Sense current 410 is then measured at either first bit line 133 or third bit line 111 and the resistance of first MTJ 110 is determined based on the measured magnitude of sense current 410. If it is determined that the resistance of first MTJ 110 is high, a 1 logic value is read from first MTJ 110. Alternatively, if it is determined that the resistance of first MTJ 110 is low, a 0 logic value is read from first MTJ 110.

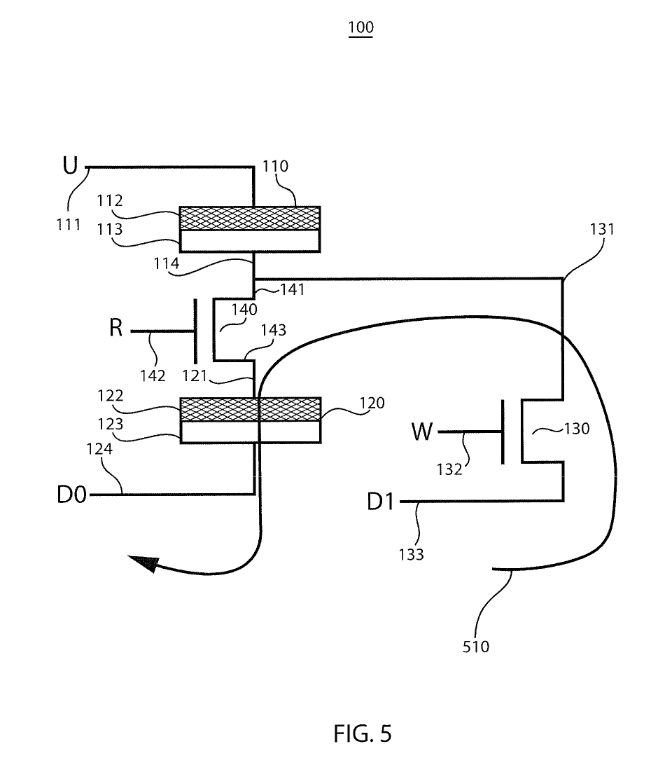

Referring to FIG. 5, a schematic view of a read operation of a second single-bit for one illustrative embodiment of the dual-cell STTRAM according to the present principles is illustrated. As shown in FIG. 5, the second single-bit stored in second MTJ 120 is read by passing a sense current 510 trough second MTJ 120 via first transistor 130 and second transistor 140 in series. Specifically, gate 132 (W) and gate 142 are each set high to turn on both first transistor 130 and second transistor 140. Third bit line 111 (U) and first bit line 133 (D1) are set to the same voltage. A voltage sufficient to generate sense current 510 through second MTJ 120 is then applied across second bit line 124 (D0) and first bit line 133 (D1). The magnitude of sense current 510 is not sufficient to affect the magnetic orientation of free layer 122 of second MTJ 120. Sense current 510 is measured at either first bit line 133 (D1) or second bit line 124 (D0) and the resistance of second MTJ 120 is determined based on the measured magnitude of sense current 510. If it is determined that the resistance of second MTJ 120 is high, a 1 logic value is read from second MTJ 120. Alternatively, if it is determined that the resistance of second MTJ 120 is low, a 0 logic value is read from second MTJ 120. As will be apparent to one of ordinary skill in the art, the actual resistance and current values which will define a 0 logic value and a 1 logic value will be dependent on the materials and technology used to construct the components of an illustrative embodiment of a dual-cell STTRAM according to the present principles.

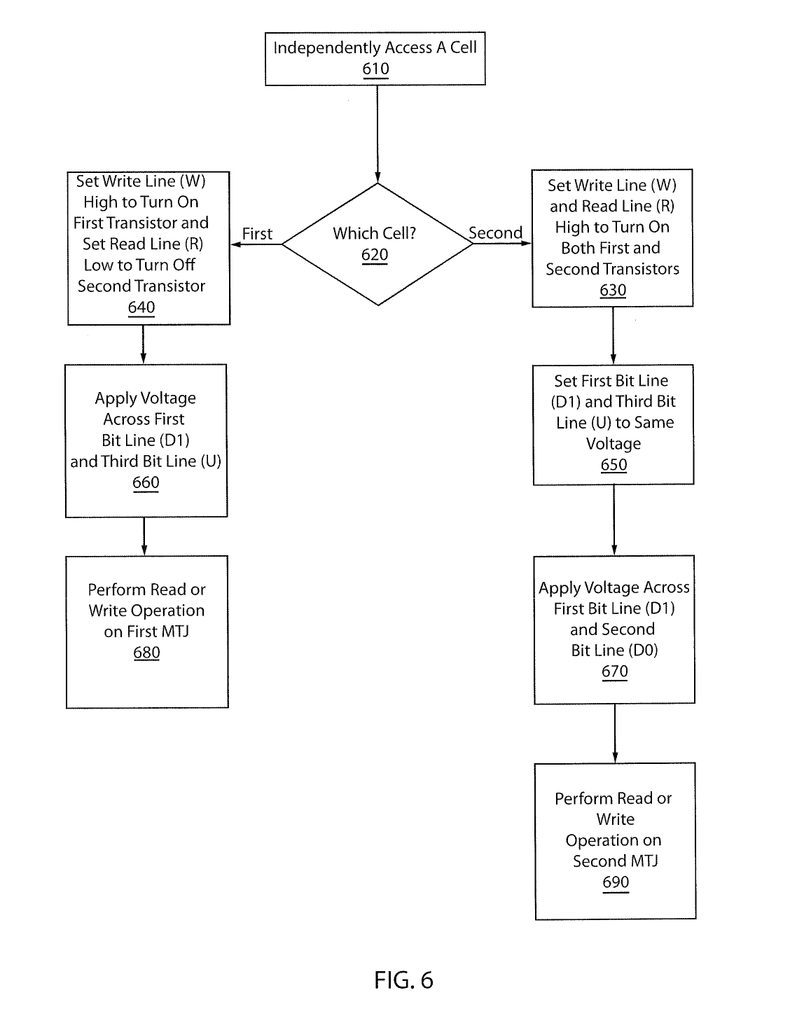

Referring to FIG. 6, a block/flow diagram of a method for independently accessing a first cell and a second cell within an illustrative embodiment of the dual-cell STTRAM according to the present principles is illustrate. As shown in FIG. 6, independent access of a cell within the dual-cell STTRAM is initiated in block 610. In block 620, it is determined which cell is being independently accessed. If the first cell is being independently accessed, in block 640, the write line (W) is set high to turn on the first transistor and the read line (R) is set low to turn off the second transistor. In block 660, a voltage across the first bit line (D1) and the third bit line (U) is applied to generate a current through the first MTJ via the first transistor. In block 680, a read or write operation is performed on the first MTJ. The magnitude and polarity of the voltage applied across the first bit line and the third bit line defines whether a read or a write operation is performed as well as the logic value that is written during a write operation.

Alternatively, if the second bit cell is being independently accessed, in block 630, the write line (W) and the read line (R) are each set high to turn on both the first and second transistors. In block 650, the first bit line (D1) and the third bit line (U) are set to the same voltage. In block 670, a voltage is applied across the third bit line (U) and the second bit line (D0) to generate a current through the second MTJ via the first and second transistors in series. In block 690, a read or write operation is performed on the second MTJ. The magnitude and polarity of the voltage applied across the first bit line and the second bit line defines whether a read or write operation is performed as well as the logic value that is written during a write operation.

Accordingly, the internal structure of the illustrative embodiment includes an access circuit capable of also independently reading each of two stored single-bits within a dual-cell STTRAM. As will be noted by one of ordinary skill in the art, the access circuit described in the illustrative embodiment may be designed using other devices and configurations capable of also independently reading each of the two stored single-bits within a dual-cell STTRAM.

The internal structure of an illustrative embodiment of a dual-cell STTRAM of the present principles also provides for a logical combination of the two stored single-bits implemented as a single read operation.

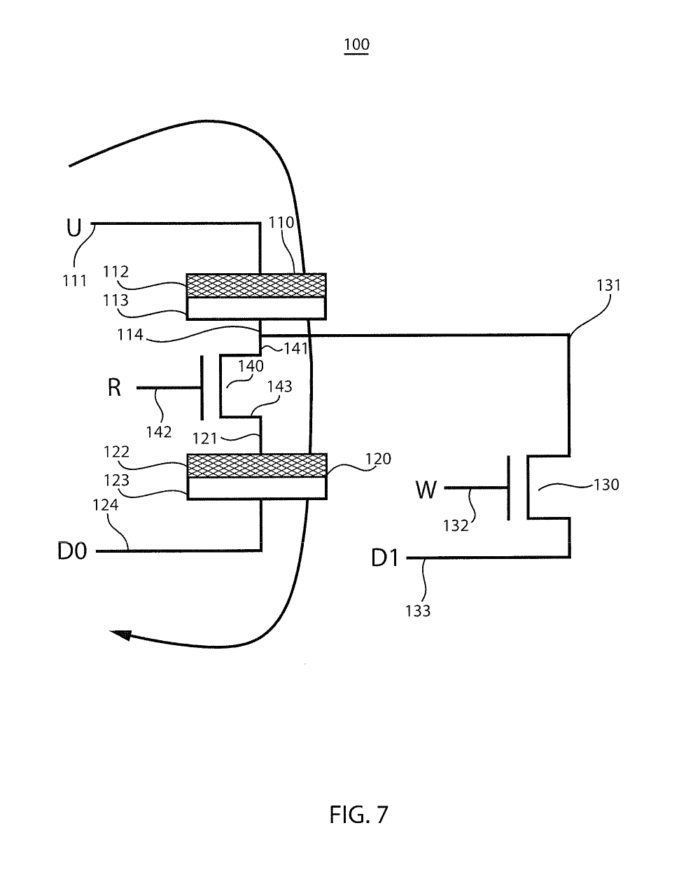

Referring to FIG. 7, a schematic view of a read operation of a logical combination of the first and second cells for one illustrative embodiment of dual-cell STTRAM according to the present principles is illustrated. As shown in FIG. 7, a combined net resistance of first MTJ 110 and second MTJ 120 may be read by a sense current 710 flowing through both first MTJ 110 and second MTJ 120 in series via second transistor 140. Specifically, gate 142 (R) is set high to turn on second transistor 140 and gate 132 (W) is set low to turn off first transistor 130. First bit line 133 (D1) and second bit line 124 (D0) are set to the same voltage. A voltage sufficient to create sense current 710 is then applied across third bit line 111 (U) and second bit line 124 (D0). Sense current 710 is measured at either third bit line 111 (U) or second bit line 124 (D0) and the combined net resistance of first MTJ 110 and second MTJ 120 is determined based on magnitude of sense current 710. The measured combined net resistance determines the result of the logical combination of the two logic values stored in first MTJ 110 and second MTJ 120.

For illustrative purposes only, an AND type logical combination may be implemented using the combined net resistance of first MTJ 110 and second MTJ 120 according to the following table,

| First MTJ | Second MTJ | Net Combined | Logic Value Assigned |
|---|---|---|---|
| Resistance | Resistance | Resistance | to Combination |
| High | High | High + High | 1 |
| High | Low | High + Low | 0 |
| Low | High | Low + High | 0 |
| Low | Low | Low + Low | 0 |

As shown, an AND operation may assign a 1 logic value to a logical combination when the combined net resistance of both first MTJ 110 and second MTJ 120 is distinguishably greater than the combined net resistance of a high resistance on one MTJ and a low resistance on the other MTJ. A threshold resistance that differentiates between a high resistance and a low resistance will depend on the materials, components and configuration used to construct the dual-cell STTRAM and can be determined using empirical information.

Similarly, also for illustrative purposes only, an OR logical combination may be implemented using the combined net resistance of first MTJ 110 and second MTJ 120 according to the following table,

| First MTJ | Second MTJ | Net Combined | Logic Value Assigned |
|---|---|---|---|
| Resistance | Resistance | Resistance | to Combination |
| High | High | High + High | 1 |
| High | Low | High + Low | 1 |
| Low | High | Low + High | 1 |
| Low | Low | Low + Low | 0 |

As shown, an OR operation may assign a 1 logic value to a logical combination when the combined net resistance of both first MTJ 110 and second MTJ 120 is distinguishably greater than a combined net resistance of a low resistance on both the first MTJ 110 and the second MTJ 120. As one of ordinary skill in the art will note, other logical combinations may be implemented by defining other appropriate combined net resistance ranges.

Referring again to FIG. 7, it is also possible to read the first cell alone while simultaneously reading the logical combination of the first and second cells, as described above. Specifically, rather than turning first transistor 130 off while reading the logical combination of first MTJ 110 and second MTJ 120, write line 132 (W) is set high to also turn first transistor 130. A suitable voltage is then applied across third bit line 111 (U) and first bit line 133 (D1) to provide for a second sense current that flows through first MTJ 110 alone via first transistor 130. This second sense current is measured at first bit line 133 (D1) and the logic value stored in first MTJ 110 alone may be determined.

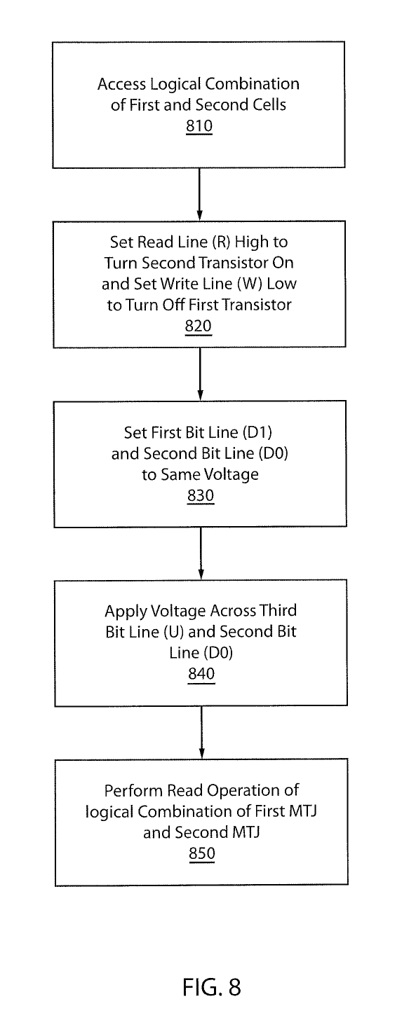

Referring to FIG. 8, a block/flow diagram of a method for a read operation of a logical combination of the first and second cells within an illustrative embodiment of the dual-cell STTRAM according to the present principles is illustrated. As shown in FIG. 8, a read operation of the logical combination of the first and second cells is initiated in block 810. In block 820, the read line (R) is set high to turn on the second transistor and the write line (W) is set low to turn off the first transistor. In block 830, the first bit line (D1) and the second bit line (D0) are set to the same voltage. In block 840, a voltage is applied across the third bit line (U) and the second bit line (D0) to generate a sense current through both the first MTJ and the second MTJ in series. In block 850, a read operation of the logical combination of the first and second MTJs is performed based on the measured magnitude of the sense current.

Accordingly, the structure of the illustrative embodiment includes an access circuit capable also of a read operation of a logical combination of the two single-bits stored within a dual-cell STTRAM. As will be noted by one of ordinary skill in the art, the access circuit described in the illustrative embodiment may be designed using other devices and configurations capable of the described read operation of a logical combination of the two single-bits stored within a dual-cell STTRAM.

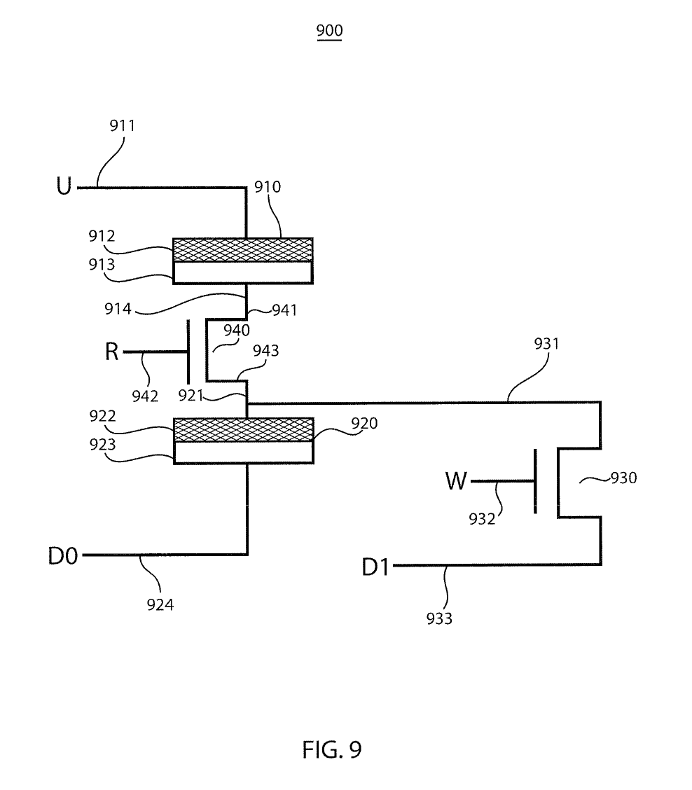

Referring to FIG. 9, a schematic view of another illustrative embodiment of a dual-cell STTRAM according to the present principles is illustrated. As show in FIG. 9, the configuration of a dual-cell STTRAM 900 differs from the previously described configuration in that a drain 931 of a first transistor 930 is electrically coupled to a free layer 922 of a second MTJ 920. In this illustrative embodiment of a dual-cell STTRAM according to the present principles, accessing first MTJ 910 requires that both first transistor 930 and second transistor 940 are turned on to provide for a current flow between first bit line 933 (D1) and third bit line 911 (U) through first MTJ 910. Also, accessing second MTJ 920 requires that first transistor 930 be turned on and that second transistor 940 be turned off to provide for a current flow between first bit line 933 (D1) and second bit line 924 (D0) through second MTJ 920. As preciously discusses, a read operation of a logical combination of first MTJ 910 and second MTJ 920 requires that first transistor 930 be turned off and that second transistor 940 be turned on to enable a current between second bit line 924 (D0) and third bit line 911 (U) through both first MTJ 910 and second MTJ 920 in series.

The illustrative embodiments of a dual-cell STTRAM according to the present principles have been described using single-level cell (SLC) MTJs. A SLC MTJ includes a free layer with a single magnetic domain whose orientation is changeable. Since this free layer has a single magnetic domain, it is capable of storing only a single-bit. However, the illustrative embodiments of a dual-cell STTRAM according to the present principles also encompass structures comprised of multi-level cell (MLC) MTJs. A MLC MTJ includes a free layer with two magnetic domains with different magnetic properties whose orientations are changeable. Since this free layer has two magnetic domains, it is capable of storing two single-bits. The magnetic orientation of one domain (soft domain) can be switched by a small current while that of the other domain (hard domain) can be switched only by a larger current. Four combinations of the magnetic orientations of the two domains on the free layer relative the pinned layer correspond to four resistance states. The first and second stored bits are defined by the magnetic orientations of the hard and soft domains, respectively, relative to the pinned layer.

Having described preferred embodiments of a system and method (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A dual-cell spin-transfer torque random-access memory, comprising:
a first magnetic tunneling junction;
a second magnetic tunneling junction; and
an access circuit coupled to the first and second magnetic tunneling junctions such that independent read and write access is provided to bits stored in the first and second magnetic tunneling junctions.

2. The dual-cell spin-transfer torque random-access memory of claim 1, wherein the access circuit is coupled to the first and second magnetic tunneling junctions such that a logical combination of the bits stored in the first and second magnetic tunneling junctions is provided.

3. The dual-cell spin-transfer torque random-access memory of claim 2, wherein the logical combination of the bits stored in the first and second magnetic tunneling junctions is a function of the combined net resistance of the first and second magnetic tunneling junctions.

4. The dual-cell spin-transfer torque random-access memory of claim 1, wherein the first and second magnetic tunneling junctions include a first ferromagnetic layer having a permanent magnetic polarity and a second ferromagnetic layer having a changeable magnetic polarity separated by a thin insulating layer.

5. The dual-cell spin-transfer torque random-access memory of claim 1, wherein the access circuit includes a first transistor and a second transistor.

6. The dual-cell spin-transfer torque random-access memory of claim 5, wherein the first and second transistors are negative field effect transistors.

7. The dual-cell spin-transfer torque random-access memory of claim 5, wherein the first and second transistors are positive field effect transistors.

8. The dual-cell spin-transfer torque random-access memory of claim 1, wherein the access circuit includes a first bit line, a second bit line, a third bit line, a write line and a read line.

9. A dual-cell spin-transfer torque random-access memory, comprising:
a first magnetic tunneling junction;
a second magnetic tunneling junction; and
a first transistor and a second transistor providing independent read and write access to bits stored in the first and second magnetic tunneling junctions and providing a logical combination of bits stored in the first and second magnetic tunneling junctions.

10. The dual-cell spin-transfer torque random-access memory of claim 9, wherein the first and second magnetic tunneling junctions each include a first ferromagnetic layer having a permanent magnetic polarity and a second ferromagnetic layer having a changeable magnetic polarity separated by a thin insulating layer.

11. The dual-cell spin-transfer torque random-access memory of claim 10, wherein a second bit line is electrically coupled to the first ferromagnetic layer of the second magnetic tunneling junction and a third bit line is electrically coupled to the second ferromagnetic layer of the first magnetic tunneling junction.

12. The dual-cell spin-transfer torque random-access memory of claim 10, wherein the second transistor includes a drain electrically coupled to the first ferromagnetic layer of the first magnetic tunneling junction and a source electrically coupled to the second ferromagnetic layer of the second magnetic tunneling junction.

13. The dual-cell spin-transfer torque random-access memory of claim 10, wherein the first transistor includes a drain electrically coupled to the first ferromagnetic layer of the first magnetic tunneling junction.

14. The dual-cell spin-transfer torque random-access memory of claim 10, wherein the first transistor includes a drain electrically coupled to the second ferromagnetic layer of the second magnetic tunneling junction.

15. The dual-cell spin-transfer torque random-access memory of claim 9, wherein the first and second transistors are negative field effect transistors.

16. The dual-cell spin-transfer torque random-access memory of claim 9, wherein the first and second transistors are positive field effect transistors.

17. The dual-cell spin-transfer torque random-access memory of claim 9, wherein the first transistor includes a source electrically coupled to a first bit line and a gate electrically coupled to a write line.

18. The dual-cell spin-transfer torque random-access memory of claim 9, wherein the second transistor includes a gate electrically coupled to a read line.

19. A method of accessing a dual-cell spin-transfer torque random-access memory comprising the steps of:
generating a current flow through a first magnetic tunneling junction to access a first cell;
generating a current flow through a second magnetic tunneling junction to access a second cell; and
generating a current flow through both the first and the second magnetic tunneling junctions in series to access a logical combination of the first and second cells.

20. The method of accessing a dual-cell spin-transfer torque random-access memory of claim 19, wherein the current flow through the first magnetic tunneling junction is enabled by turning on a first transistor via a read line.

21. The method of accessing a dual-cell spin-transfer torque random-access memory cell of claim 20, wherein the current flow through the first magnetic tunneling junction is generated by applying a voltage across a first bit line electrically coupled to a source of the first transistor and a third bit line electrically coupled to the first magnetic tunneling junction.

22. The method of accessing a dual-cell spin-transfer torque random-access memory of claim 19, wherein the current flow through the second magnetic tunneling junction is enabled by turning on a first transistor via a read line and a turning on a second transistor via a write line.

23. The method of accessing a dual-cell spin-transfer torque random-access memory cell of claim 22, wherein the current flow through the second magnetic tunneling junction is generated by applying a voltage across a first bit line electrically coupled to a source of the first transistor and a second bit line electrically couple to the second magnetic tunneling junction.

24. The method of accessing a dual-cell spin-transfer torque random-access memory cell of claim 19, wherein the current flow through the first and second magnetic tunneling junctions in series is enabled by turning on a second transistor via a write line.

25. The method of accessing a dual-cell spin-transfer torque random-access memory cell of claim 24, wherein the current flow through the first and second magnetic tunneling junctions in series is generated by applying a voltage across a third bit line electrically coupled to the first magnetic tunneling junction and a second bit line electrically coupled to the second magnetic tunneling junction.
